(19) United States
(12) Patent Application Publication
(10) Pub. No.: US 2002/0019128 A1
(43) Pub. Date: Feb. 14, 2002

(54) Slurry for chemical mechanical polishing of metal layer, method of preparing the slurry, and metallization method using the slurry

(76) Inventors: Jong-Won Lee, Sungnam-city (KR); Bo-Un Yoon, Seoul (KR); Sang-Rok Hah, Seoul (KR)

Correspondence Address: JONES VOLENTINE, L.L.C., Suite 150, 12200 Sunrise Valley Drive, Reston, VA, 20191, US

(21) Appl. No.: 09/816,365

(22) Filed: Mar. 26, 2001

(30) Foreign Application Priority Data
Jun. 5, 2000 (KR) 00-30800

(51) Int. Cl. H01L 21/4763

(52) U.S. Cl. 438/645

(57) ABSTRACT

A slurry for use in chemical mechanical polishing (CMP) of a metal layer. The CMP slurry includes an abrasive, a plurality of oxidizing agents, a stabilizer including an organic acid having a carboxyl group, a corrosion inhibitor which suppresses corrosion of a metal, a fluorine compound which reduces a difference in removal rates of a metal layer and a barrier layer, and deionized water. The plurality of oxidizing agents include a second oxidizing agent which oxidizes the metal and a first oxidizing agent which restores an oxidizing ability of the second oxidizing agent.

### BACKGROUND OF THE INVENTION

1. Field of the Invention

The present invention relates to a chemical mechanical polishing (CMP) slurry for use in the fabrication of semiconductor devices, and more particularly, the present invention relates to a CMP slurry, to a method of preparing the CMP slurry, and to a metallization method using the CMP slurry.

2. Description of the Related Art

To achieve further miniaturization of semiconductor devices having increased densities and multilevel interconnections, techniques have been utilized which allow for the formation of very fine patterns. The resultant surface structures of such semiconductor devices have become highly complex, and are typically characterized by increased step height differences at interlevel layers formed therein. Generally, such step differences can cause a number of well-known fabrication problems. As such, in an effort to eliminate or minimize step differences within the layers of a semiconductor device as it is manufactured, it is known to subject certain layers to a variety of planarization processes. One such planarization process is known as chemical mechanical polishing (CMP). In particular, CMP has been extensively used in the formation of metal conductive layers, such as metal interconnections, contact plugs and via contacts.

Recent efforts have focused on improving the slurries which are used in the CMP of metal layers. For example, U.S. Pat. No. 5,993,686 discloses a two package system CMP slurry which includes a first package made up of an aqueous solution containing an oxidizing agent and a fluorine containing additive, and a second package which contains an aqueous dispersion of abrasive. U.S. Pat. No. 5,980,775 discloses a CMP composition which includes the mixture of a first component having at least one oxidizing agent, and a second component which contains the product of the mixture of at least one catalyst having multiple oxidation states and at least one stabilizer. U.S. Pat. No. 5,340,370 discloses a CMP slurry which is made up an oxidizing agent, an abrasive and water, and which has a pH between 2 and 4.

FIGS. 1A through 1C are sectional views illustrating the effect of CMP slurry characteristics on the configuration of metal interconnections in a general metallization process.

An insulating layer 20 of an oxide is deposited over a semiconductor substrate 10, and a plurality of trenches are formed in the insulating layer 20 by photolithography and dry etching. Then, a barrier layer 30 of Ti, TiN, Ta or TaN and a metal layer 40 of W, Al or Cu are sequentially deposited within the trenches and over the insulating layer 20 as shown in FIG. 1A.

Next, the metal layer 40 and the barrier layer 30 are removed by a CMP process down to a level of the insulating layer 20, so that conductive layers 40a and their underlying barrier layers remain in the trenches. The conductive layers 40a may serve as interconnection layers, plugs, or via contacts.

Conventional CMP slurries exhibit a predetermined polishing selectivity with respect to the metal layer 40 and the barrier layer 30. This results in the polishing rate (i.e., removal rate) of the metal layer 40 being different from that of the barrier layer 30. Usually, the barrier layer 30 is polished more slowly than the metal layer 40. For this reason, if the CMP is continued until the entire conductive layer is removed down to a desired level, certain material layers or portions thereof can be excessively removed. For example, as shown in FIG. 1B, the different CMP polishing rates of the material layers may result in a portion of the insulating layer 20 over the semiconductor substrate 10 being eroded below a predetermined level L.

For effective formation of a conductive layer, the polishing rate of the metal layer 40 should be on the order of at least 2000 Å/min. In order to enhance the removal rate to such a level, some conventional CMP slurries contain an excessive amount of oxidizing agent. However, the excess oxidizing agent can increase the degree of corrosion of the metal. As a result, as shown in FIG. 1C, the conductive layers 40a may be disadvantageously formed with reduced thicknesses. Also, as the amount of oxidizing agent in the slurry increases, the manufacturing costs increase and the stability of the slurry over time may degrade.

Nevertheless, the use of an oxidizing agent in CMP slurries is known to significantly influence the slurry characteristics. The oxidizing agent takes electrons from the metal through an oxidation reaction, and is reduced itself. Meanwhile, the metal which has lost electrons combines with oxygen of the slurry to form a metal oxide layer, or is dissolved in the slurry and present in the form of negative metal ions combined with oxide. The metal oxide layer can be more easily removed than a single metal layer, thus enhancing the removal rate. That is, the metal oxide layer can be removed by the frictional force working between the abrasive and a polishing pad.

As for conventional CMP slurries which use hydrogen peroxide as an oxidizing agent, the hydrogen peroxide has a tendency to decompose due to reaction with other chemicals present in the slurry. As a result, the concentration of the oxidizing agent in the slurry decreases, which reduces the lifecycle of the slurry. To avoid this problem, additional hydrogen peroxide is almost always added to the slurry just before application of the slurry in the CMP process.

However, the provision of an automatic mechanism to allow hydrogen peroxide to be added to the slurry just before the CMP process adds to the overall complexity and cost of the slurry supply apparatus, and also necessitates a hydrogen peroxide storage facility. On the other hand, manual addition of the hydrogen peroxide is highly inconvenient, and increases the probability of that mistakes will be made, thus decreasing the reliability of the slurry characteristics.

### SUMMARY OF THE INVENTION

It is an object of the present invention to provide a chemical mechanical polishing (CMP) slurry for a metal layer which has a minimal amount of an oxidizing agent, and which enables enhanced stability of the slurry over time and reduced manufacturing costs.

It is another object of the present invention to provide a method for preparing a CMP slurry for a metal layer, which improves the stability of the slurry over time, to thereby facilitate handling and storage of the slurry.

It is still another object of the present invention to provide a method of metallization of a semiconductor memory device, which eliminates or minimizes a reduction in the thickness of a metal layer caused by corrosion, and erosion of an oxide layer resulting from a difference in removal rates among layers.

According to one aspect of the present invention, there is provided a slurry which includes an abrasive, a plurality of oxidizing agents, a stabilizer including an organic acid having a carboxyl group, a corrosion inhibitor which suppresses corrosion of a metal, a fluorine compound which reduces a difference in removal rates of a metal layer and a barrier layer, and deionized water. The plurality of oxidizing agents include a second oxidizing agent which oxidizes the metal and a first oxidizing agent which restores an oxidizing ability of the second oxidizing agent. The slurry may further include a pH adjuster.

Accordingly to another aspect of the present invention, there is provided a slurry which includes a first solution including a first oxidizing agent, an abrasive and deionized water; and a second solution including a second oxidizing agent which oxidizes a metal, a stabilizer which includes an organic acid having a carboxyl group, a corrosion inhibitor which suppresses corrosion of the metal, a fluorine compound which reduces a difference in removal rates of a metal layer and a barrier layer, and deionized water. The first oxidizing agent of the first solution restores an oxidizing ability of the second oxidizing agent of the second solution.

According to still another aspect of the present invention, there is provided a method for preparing a slurry, which includes preparing a first solution including a first oxidizing agent, an abrasive and deionized water; and preparing a second solution including a second oxidizing agent which oxidizes a metal, a stabilizer which includes an organic acid having a carboxyl group, a corrosion inhibitor which suppresses corrosion of the metal, a fluorine compound which reduces a difference in removal rates of a metal layer and a barrier layer, and deionized water. The first solution is diluted with deionized water, and then mixed with the second solution. The first oxidizing agent of the first solution restores an oxidizing ability of the second oxidizing agent of the second solution.

According to yet another aspect of the present invention, there is provided a method of metallization of a semiconductor device, which includes forming a barrier layer over an oxide layer having a stepped surface. Next, a metal layer is formed over the barrier layer, and a portion of the metal layer and the barrier layer are removed by chemical mechanical polishing using the slurry described above.

The CMP slurry for a metal layer according to the present invention enables improvement in the removal rate of the metal layer using a reduced amount of oxidizing agent, as well as improvement in the stability of the slurry over time. Also, the corrosion of a metal can be suppressed, and erosion of an oxide layer can be avoided by reducing the difference in removal rates of a metal layer and a barrier layer. A slurry with improved reproducibility can be obtained, thus improving the reproducibility of CMP process itself.

### BRIEF DESCRIPTION OF THE DRAWINGS

The above objectives and advantages of the present invention will become more apparent from the detail description of the preferred embodiments which follows, with reference to the attached drawings, in which:

FIGS. 1A through 1C are sectional views for describing the effects of the characteristics of a chemical mechanical polishing (CMP) slurry used in a general metallization process on a metal interconnection structure;

FIG. 2 illustrates the mechanism of oxidation in a CMP process applied to a tungsten layer with a slurry according to an embodiment of the present invention;

FIG. 3 is a graph illustrating the tungsten removal rates by CMP with respect to the type of oxidizing agent contained in a slurry of an embodiment of the present invention;

FIG. 4 is a graph illustrating the tungsten removal rates with respect to time elapsed after the preparation of a slurry of an embodiment of the present invention;

FIG. 5 is a graph illustrating the metal corrosion rates with respect to the concentration of EDTA-diamminium salt hydrate contained in a slurry of an embodiment of the present invention;

FIG. 6 is a graph illustrating variations in hydrogen peroxide concentration with respect to time elapsed after the preparation of a slurry of an embodiment of the present invention;

FIG. 7 is a graph illustrating the tungsten removal rates by a CMP with respect to time elapsed after the preparation of a slurry of an embodiment of the present invention;

FIG. 8 is a flowchart illustrating a method for preparing a CMP slurry for a metal layer according to a preferred embodiment of the present invention; and

FIG. 9 is a sectional view of metal interconnections of a semiconductor device formed using a slurry of an embodiment of the present invention.

### DETAILED DESCRIPTION OF THE INVENTION

A slurry according to the present invention is for use in chemical mechanical polishing (CMP) of a metal layer. Typically, the metal layer is formed of, for example, tungsten (W), aluminum (Al) and/or copper (Cu), and serves as a conductive layer in a semiconductor device, such as a metal interconnection layer, a contact plug or a via contact.

The CMP slurry of the invention includes at least two kinds of oxidizing agents, which chemically react with the metal layer to cause oxidation of the metal layer by chemical reaction. The CMP slurry further includes an abrasive for mechanical polishing of the oxidized metal, and deionized water.

Suitable abrasives used in the slurry according to the present invention include, for example, silica, alumina, ceria, titania, zirconia and germania. Among these abrasives, silica is considered to be the most effective. The amount of abrasive is in the range of 3-25% by weight based on the total weight of the slurry, with 3-10% by weight being preferred. If the amount of the slurry is less than 3% by weight, it is difficult to polish the metal layer at a desired rate. In contrast, if the amount of the slurry exceeds 10% by weight, the stability of the slurry tends to drop slightly over time.

The at least two kinds of oxidizing agents added to the CMP slurry include a first oxidizing agent and a second oxidizing agent. The first oxidizing agent has a relatively strong oxidizing ability due to its high reduction potential, but a relatively low reaction rate to metal. The second oxidizing agent has a weak oxidizing ability relative to the first oxidizing agent, but a higher reaction rate to metal than the first oxidizing agent. Thus, the oxidation of the metal by the first oxidizing agent is relatively slow and the etching reaction rate is retarded by the first oxidizing agent. Meanwhile, the metal can be easily oxidized by the second oxidizing agent. Here, as the second oxidizing agent oxidizes metal, the second oxidizing agent itself is reduced. In turn, the reduced second oxidizing agent is oxidized by the first oxidizing agent, so that the oxidizing ability of the second oxidizing agent is restored.

An example of the first oxidizing agent is hydrogen peroxide (H₂O₂), and an example of the second oxidizing agent is ferric nitrate (Fe(NO₃)₃).

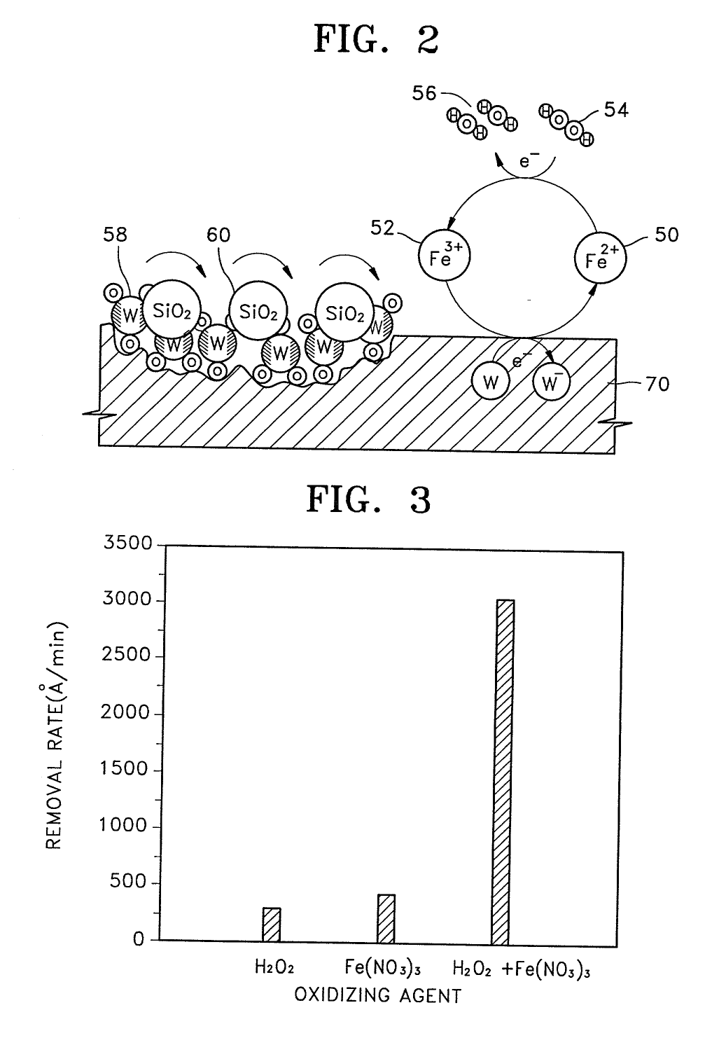

FIG. 2 illustrates the mechanism of oxidation during CMP with respect to a tungsten layer 70 using the slurry of the present invention which contains which contains at least two kinds of oxidizing agents. Fe³⁺ ions 52 originating from the second oxidizing agent having a high reaction rate, i.e., Fe(NO₃)₃, is reduced to Fe²⁺ ions by taking electrons from the tungsten (W). The W that has lost electrons combines with oxygen and changes into negative ions. Hydrogen peroxide 54 is reduced to water 56 by taking electrons from Fe²⁺ ions 50, so that Fe²⁺ ions 50 are restored to Fe³⁺ ions 52. The second oxidizing agent, i.e., Fe(NO₃)₃, itself is reduced by oxidizing W, and in turn oxidized back by the first oxidizing agent, i.e., hydrogen peroxide 54. By doing so, reduction and oxidation of the second oxidizing agent are repeatedly recycled. As a result, recycling of the second oxidizing agent is possible, and CMP can be achieved at a high removal rate with a small amount of oxidizing agent. W, which exists in the form of negative ions in combination with oxygen, combines with oxygen contained in the slurry to form an oxide layer 58. The oxide layer 58 can be easily removed by the frictional force of the solid silica 60, used as an abrasive, and a polishing pad (not shown).

In a CMP with the slurry of the present invention, the second oxidizing agent is reduced by oxidation reaction with metal, and in turn is oxidized by the first oxidizing agent, so that the oxidizing ability of the second oxidizing agent is restored, which allows the second oxidizing agent to participate in another oxidation reaction with metal. As a result, with a reduced amount of the oxidizing agent, the removal efficiency of metal can be enhanced.

In addition to hydrogen peroxide (H₂O₂), other suitable first oxidizing agents include a peroxide, such as benzoyl peroxide, calcium peroxide, barium peroxide and sodium peroxide. The amount of the first oxidizing agent is in the range of 0.01-10% by weight based on the total weight of the slurry, with 0.5-5% by weight being preferred.

In addition to ferric nitrate (Fe(NO₃)₃), other suitable second oxidizing agents include a ferric salt and a ferric compound, for example, potassium ferricyanide, ferric phosphate and ferric sulfate. Preferably, the second oxidizing agent is added in an amount of 0.001-5% by weight based on the total weight of the slurry, with 0.05-0.5% by weight being more preferred.

FIG. 3 is a graph illustrating the removal rates of the W layer by CMP with respect to the type of oxidizing agent used in the slurry. For the evaluation, three slurries were prepared. The first slurry contained hydrogen peroxide as an oxidizing agent, the second contained ferric nitrate as an oxidizing agent, and the third contained both hydrogen peroxide and ferric nitrate as oxidizing agents. Here, silica was used as an abrasive for all the slurries. A W layer was subjected to CMP with each of the slurries.

As shown in FIG. 3, where hydrogen peroxide (in an amount of 1% by weight based on the total weight of the slurry) or ferric nitrate (in an amount of 0.05% by weight based on the total weight of the slurry) is used alone, the tungsten removal rate was very low at 500 Å/min or less. In contrast, a relatively high tungsten removal rate of about 3000 Å/min was obtained when using the slurry containing two oxidizing agents, i.e., hydrogen peroxide (in an amount of 1% by weight based on the total weight of the slurry) and ferric nitrate (in an amount of 0.05% by weight based on the total weight of the slurry).

Thus, the slurry of the present invention exhibits an improvement in the removal rate.

It is preferred, however, that steps be taken to enhance the stability of slurry over time. Otherwise, the removal rate of a metal layer using the slurry cannot readily be maintained during the time that elapses after the preparation of slurry.

Accordingly, to improve the stability of slurry over time, a stabilizer which includes an organic acid is further added to the CMP slurry according to an embodiment of the present invention. The stabilizer includes an organic acid with carboxyl group, for example, acetic acid, citric acid, glutaric acid, glycolic acid, formic acid, lactic acid, malic acid, maleic acid, oxalic acid, phthalic acid, succinic acid and tartaric acid. Among these organic acids, citric acid is most preferred. Preferably, the stabilizer is added in an amount of 0.01-10% by weight based on the total weight of the slurry, with 0.5-2% by weight being more preferred.

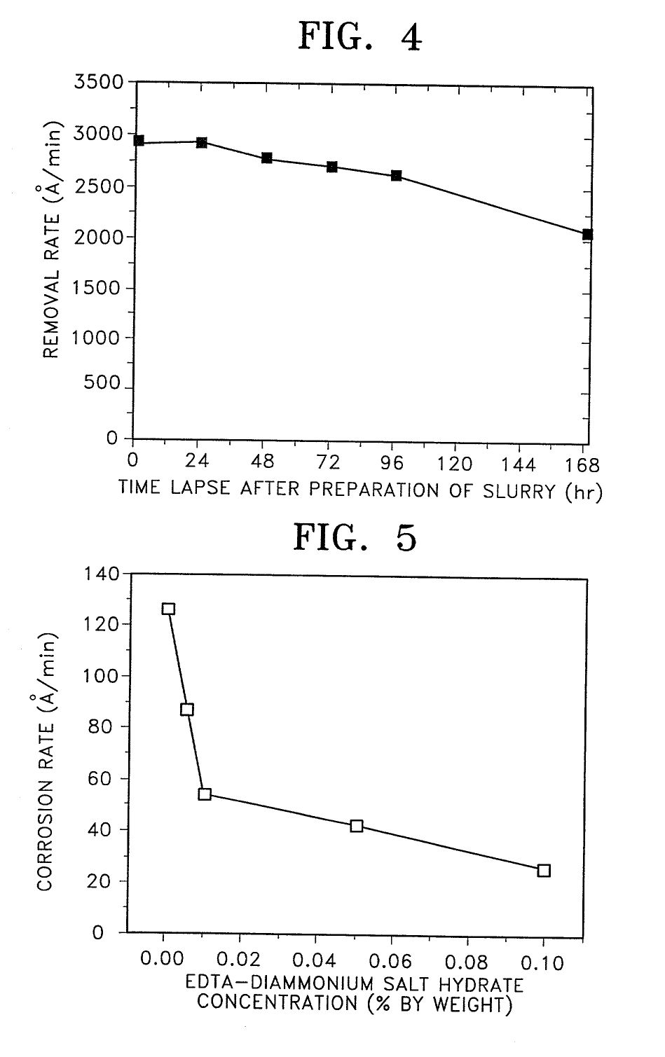

FIG. 4 is a graph illustrating variations in tungsten removal rate with respect to the time elapsed after the preparation of a slurry which includes a citric acid as a stabilizer. In this example, the CMP was carried out on a tungsten layer using the slurry. It is apparent from FIG. 4 that the reproducibility of tungsten removal rate is favorable by virtue of chelation with the carboxyl group of citric acid added to the slurry.

The CMP slurry according to an embodiment of the present invention also contains a corrosion inhibitor for suppressing corrosion of metal. As the corrosion inhibitor, athylenediamine tetraacetic acid (EDTA), or an EDTA salt can be added to the slurry. Suitable EDTA salts include, for example, an EDTA-calcium disodium salt, an EDTA-diammonium salt, an EDTA dipotassium salt, an EDTA-iron (lll) sodium salt, an EDTA-magnesium disodium salt, an EDTA-tetrasodium salt, an EDTA-tripotassium salt, an EDTA-trisodium salt, and ethylenediaminetetraacetic dianhydride. Among these EDTA salts, EDTA-diammonium salt hydrate is more preferred as a corrosion inhibitor.

The corrosion inhibitor may be added in an amount of 0.001-0.1% by weight based on the total weight of slurry, with 0.005-0.05% by weight being preferred. If the amount of corrosion inhibitor is less than 0.005% by weight, corrosion may not be effectively suppressed. If the amount of corrosion inhibitor exceeds 0.05% by weight, metal corrosion can be effectively avoided, but with a tendency towards slight reduction of the metal removal rate.

FIG. 5 is a graph illustrating variations in metal corrosion rate with respect to the EDTA-diammonium salt hydrate concentration in the slurry according to the present invention. For the evaluation, five sample slurries were prepared by varying the amount of EDTA-diammonium salt hydrate. The amount of components other than EDTA-diammonium salt hydrate were the same for all five slurries. A tungsten layer was exposed to a CMP with each of the sample slurries, and the tungsten corrosion rate was measured. As shown in FIG. 5, when compared with the slurry containing no EDTA-diammonium salt hydrate, the slurry having 0.01% by weight EDTA-diammonium salt hydrate shows about 50% reduction in the tungsten corrosion rate.

Another significant characteristic of CMP slurries is the selectivity of the metal layer relative to the barrier layer. When a tungsten layer having an underlying Ti barrier layer is exposed to CMP, the smaller the difference in CMP removal rates of W and Ti, the smaller the erosion of the neighboring oxide layer.

To minimize the erosion of the oxide layer by reducing the difference in the metal/barrier selectivity, the CMP slurry of an embodiment of the present invention includes an additive which is capable of increasing the barrier removal rate. A fluorine compound may be used as the additive. Suitable fluorine compounds include, for example, hydrofluoric acid (HF), fluorosilicic acid (H₂SiF₆), fluorotitanic acid (H₂TiF₆), fluoroboric acid (HBF₄), ammonium fluoride (NH₄F), ammonium hydrogen difluoride (NH₄HF₂), potassium fluoride (KF), potassium hydrogen difluoride (KHF₂), sodium fluoride (NaF), silver fluoride (AgF) or potassium tetrafluoroborate (KBF₄). Among these example, HF is the most effective as the additive.

The fluorine compound is added in an amount of 0.01-1% by volume based on the total volume of the slurry, with 0.01-0.1% by volume being preferred. The CMP slurry of an embodiment of the present invention may further include a pH adjuster as needed. Suitable pH adjusters may be an acid, for example, sulfuric acid, nitric acid, hydrochloric acid and phosphoric acid, with sulfuric acid being preferred. For improved dispersion stability of the slurry, it is preferable that the CMP slurry has a pH of 2-3. If the pH of the slurry is less than 2, the handling conditions may be hazardous. If the pH of the slurry exceeds 3, the dispersion stability of the slurry may degrade.

Next, a method for preparing a CMP slurry for a metal layer according to a preferred embodiment of the present invention will be described.

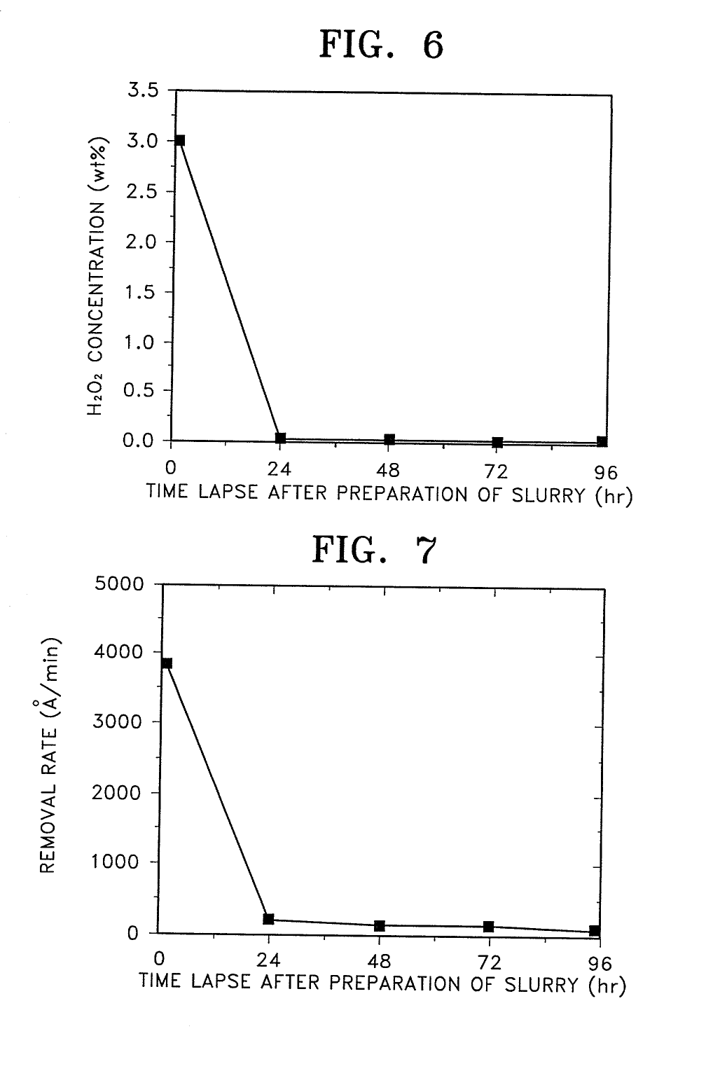

Initially, however, attention is directed to FIG. 6 which illustrates variations in H₂O₂ concentration of the slurry with time, which contains H₂O₂ as the first oxidizing agent, and Fe(NO₃)₃ as the second oxidizing agent. As shown in FIG. 6, it is apparent that the H₂O₂ concentration in the slurry containing the first and second oxidizing agents sharply decreases with time.

Turning to FIG. 7, illustrates therein are variations in tungsten removal rate for a CMP with the slurry including the first and second oxidizing agents, i.e., H₂O₂ and Fe(NO₃)₃, relative to the time elapsed after the preparation was completed. As shown in FIG. 7, as the period of time after the slurry preparation increases, the tungsten removal rate rapidly decreases.

The results shown in FIGS. 6 and 7 are considered to occur because the first oxidizing agent of the slurry continues to react with the second oxidizing agent, so that it decomposes into water and hydrogen over time. As a result, the H₂O₂ concentration in the slurry decreases, so the effect of adding two types of oxidizing agents cannot be exerted.

Accordingly, in the preparation of the CMP slurry of an embodiment of the present invention, a first solution containing the first oxidizing agent, which has an oxidizing ability greater than that of the second oxidizing agent, and a second solution containing the second oxidizing agent, are separately prepared, and then mixed to obtain the desired final slurry. Components of the first solution include the first oxidizing agent, an abrasive, and deionized water. Components of the second solution include the second oxidizing agent, a stabilizer, a corrosion inhibitor, a fluorine compound and deionized water. The fluorine compound is added so as to reduce a difference in removal rates of different conductive layers. The second solution may further include a pH adjuster and other additives.

FIG. 8 is a flowchart illustrating a method of preparing a slurry for CMP processing of a metal layer according to a preferred embodiment of the present invention. Referring to FIG. 8, in step 110, a first solution including a first oxidizing agent, an abrasive and deionized water, and a second solution including a second oxidizing agent, a stabilizer, a corrosion inhibitor, a fluorine compound and deionized water are separately prepared.

As previously mentioned, the first oxidizing agent has a stronger oxidizing ability due to its relatively high reduction potential, but has a relatively low reaction rate with metal. The types of suitable first oxidizing agents are the same as those already mentioned above. The abrasive may be, for example, silica, alumina, ceria, titania, zirconia and/or germania.

As also previously mentioned, the oxidizing ability of the second oxidizing agent is weaker than that of the first oxidizing agent, and the reaction rate thereof is higher than that of the first oxidizing agent, so that metal is susceptible to oxidize by the second oxidizing agent. The types of suitable second oxidizing agents are the same as discussed above. The stabilizer includes an organic acid with a carboxyl group. The types of suitable corrosion adhesive and fluorine compounds are the same as those discussed above. Step 110 may further include adjusting the pH of the second solution to a desired level with a pH adjuster, such as sulfuric acid, as needed.

There is no limitation as to which one of the first and second solutions is prepared first. That is, the preparation order of the first and second solutions does not influence on the effects of the invention. Likewise, the first and second solutions may be simultaneously prepared.

After the preparation of the first and second solutions is completed, and just before CMP, the first solution is diluted with deionized water (step 130). Next, the diluted first solution is mixed at a predetermined ratio with the second solution (step 140), thereby resulting in a CMP slurry according to the present invention.

In one particular embodiment, H₂O₂ and deionized water are added to a commercially available silica abrasive, to prepare the first solution. Fe(NO₃)₃ is added to and dissolved in citric acid, and deionized water, EDTA-diammonium salt hydrate and HF are added in succession to the resulting solution, so that the second solution is prepared. As needed, H₂SO₄ may be added to adjust the pH of the second solution. 20 l of slurry including an abrasive of 5% by weight based on the total weight of the slurry can then be prepared as follows. In the case where the first solution includes 25% by weight abrasive, 4 l of the first solution is diluted with 15 l of deionized water, so that 19 l of first solution with 5% by weight abrasive is obtained. In the case where the first solution includes 12.5% by weight abrasive, 8 l of the first solution is diluted with 11 l of deionized water, so that 19 l of first solution with 5% by weight abrasive is obtained. Next, 1 l of the second solution is added to the diluted first solution, thereby resulting in 20 l of slurry according to the present invention.

In the preparation of the CMP slurry according to the present invention, the first solution which contains an abrasive, and the first oxidizing agent having a relatively strong oxidizing ability, for example, H₂O₂, are prepared, and this first solution is mixed later at a predetermined ratio with the second solution, i.e., just before CMP. As a result, a slurry with improved reproducibility can be obtained, thus improving the reproducibility of CMP process itself.

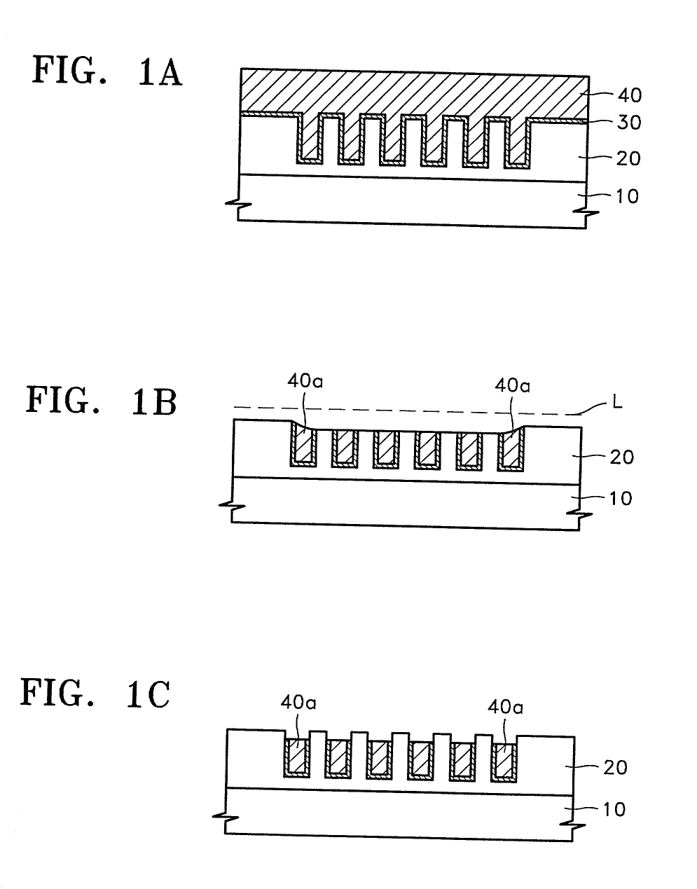

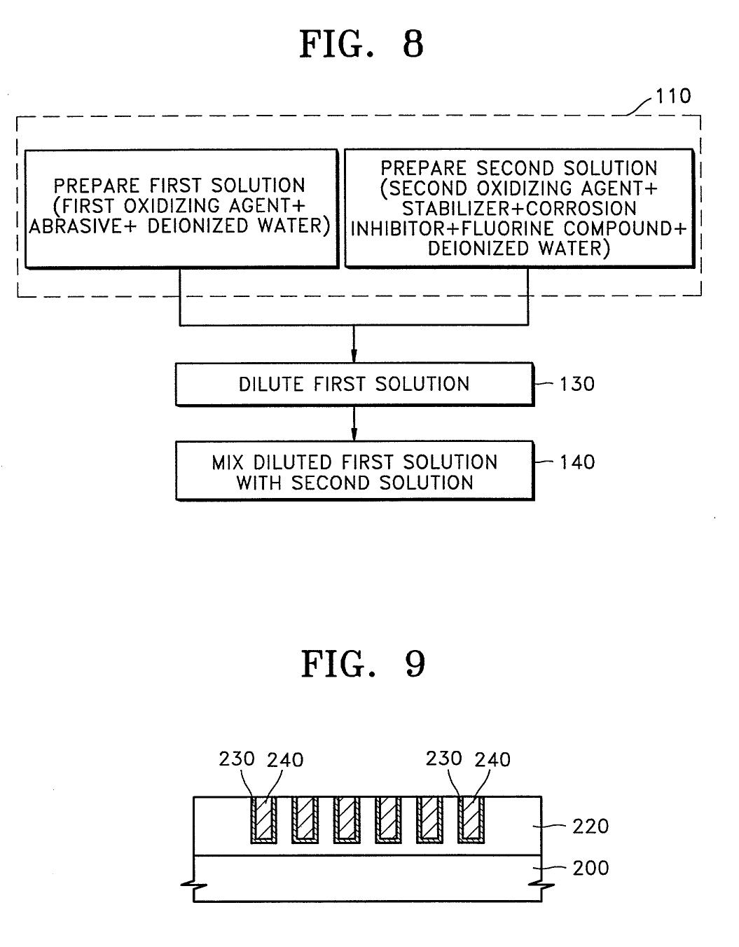

FIG. 9 is a sectional view of a metal interconnection structure of a semiconductor device, which is formed using the slurry according to an embodiment of the present invention. In particular, as previously mentioned with reference to FIG. 1A, an insulating layer 220 of oxide is deposited over a semiconductor substrate 200, and a plurality of trenches are formed in the insulating layer 220 by photolithography and dry etching, thereby forming a stepped surface on the insulating layer 220. A barrier layer 230 of Ti, TiN, Ta or TaN, and a metal layer of W, Al or Cu, are then deposited in succession. Next, the metal layer and the barrier layer 230 are removed by CMP from the top of the insulating layer 220 using the CMP slurry of the present invention, thereby resulting in conductive layers 240 within the trenches. The conductive layers may constitute interconnection layers, plugs and/or via contacts.

Using the CMP slurry of the present invention, erosion of the insulating layer, which is caused by the difference in removal rates between the metal layer and the barrier layer, and corrosion of the metal layer, are avoided or minimized. That is, referring again to FIG. 9, the insulating oxide layer 220, the conductive layer 240 and the barrier layer 230 are formed having a substantially planar surface.

### Example 1: Evaluation of slurry characteristics with respect to the amount of first oxidizing agent

H₂O₂ was used as the first oxidizing agent of the first solution, and the slurry characteristics with respect to the amount of H₂O₂ were evaluated.

For the evaluation, Fe(NO₃)₃ was used in an amount of 0.05% by weight based on the total weight of the slurry, as the second oxidizing agent added to the second solution. With the fixed amount of the second oxidizing agent, the amount of H₂O₂, the first oxidizing agent, in the first solution was varied at 0.5, 1, 2 and 3% by weight, thereby preparing four samples slurries. To form a tungsten layer to be polished, a high-temperature oxide (HTO) film was deposited over a silicon substrate to a thickness of 1000 Å, and a TiN layer and the tungsten layer were deposited in succession to a thickness of 1000 Å and 10000 Å, respectively. To form an oxide layer as another target to be polished, a plasma tetraethyl orthosilicate (P-TEOS) film was deposited over a silicon substrate to a thickness of 10000 Å.

The polishing was carried out using a PRESI CMP tool (manufactured by PRESI Co.) for a 6-inch wafer with the IC1400 stack pad and the R200 carrier film, manufactured by RODEL CO., at a down force of 4 psi, a table speed of 75 rpm, a wafer rotation speed, i.e., a carrier's spindle speed, of 35 rpm, and a slurry flow rate of 250 ml/min. The results obtained by the CMP to the tungsten layer and oxide layer with the four sample slurries are shown in Table 1.

TABLE 1

| | Amount of | Amount of | Tungsten | Oxide | |
|---|---|---|---|---|---|
| | H₂O₂ | Fe(NO₃)₃ | Removal Rate | Removal Rate | Selectivity |
| Sample No. | (% by weight) | (% by weight) | (Å/min) | (Å/min) | (Tungsten:Oxide) |
| 1 | 0.5 | 0.05 | 2293 | 25 | 91:1 |
| 2 | 1 | 0.05 | 3004 | 26 | 115:1 |
| 3 | 2 | 0.05 | 3568 | 30 | 119:1 |
| 4 | 3 | 0.05 | 4133 | 25 | 165:1 |

As shown in Table 1, with the increase in the amount of H₂O₂ used as the first oxidizing agent, the oxide removal rate almost does not change, while the tungsten removal rate gradually increases. It is apparent that as the amount of H₂O₂ increases, the selectivity of the slurry to the tungsten layer over the oxide layer increases.

Example 2: Evaluation of slurry characteristics with respect to the amount of second oxidizing agent

Fe(NO₃)₃ was used as the second oxidizing agent of the second solution, and the slurry characteristics with respect to the amount of Fe(NO₃)₃ were evaluated.

For the evaluation, H₂O₂ was used in an amount of 1% by weight based on the total weight of the slurry, as the first oxidizing agent added to the first solution. With the fixed amount of the first oxidizing agent, the amount of Fe(NO₃)₃, the second oxidizing agent, in the second solution was varied at 0.01, 0.1, 0.5 and 1% by weight, thereby preparing four sample slurries. CMP was performed under the same conditions as in Example 1 with the prepared four sample slurries, and the results are shown in Table 2.

TABLE 2

| | Amount of | Amount of | Tungsten | Oxide | |
|---|---|---|---|---|---|
| | H₂O₂ | Fe(NO₃)₃ | Removal Rate | Removal Rate | Selectivity |
| Sample No. | (% by weight) | (% by weight) | (Å/min) | (Å/min) | (Tungsten:Oxide) |
| 1 | 1 | 0.01 | 1046 | 21 | 50:1 |
| 2 | 1 | 0.1 | 2821 | 22 | 130:1 |
| 3 | 1 | 0.5 | 2997 | 22 | 136:1 |
| 4 | 1 | 1 | 3110 | 20 | 156:1 |

As shown in Table 2, with the increase in the amount of Fe(NO₃)₃ used as the second oxidizing agent, the oxide removal rate changes very slightly, while the tungsten removal rate greatly increases. As a result, there is shown an increase in the tungsten/oxide selectivity of the slurry.

Example 3: Evaluation of slurry characteristics with respect to the amount of second oxidizing agent and fluorine compound

The removal rates of a tungsten (W) layer and a titanium (Ti) layer with respect to the amounts of the second oxidizing agent in the second solution, and a fluorine compound were evaluated.

H₂O₂ and Fe(NO₃)₃ were used as the first and second oxidizing agents, respectively. While the amount of H₂0₂ was fixed at 2% by weight based on the total weight of the slurry, the amount of Fe(NO₃)₃ was varied at 0.05, 0.1 and 0.2% by weight. Also, the amount of HF was varied at 0 and 0.01 % by volume based on the total volume of the slurry, thereby resulting in 6 sample slurries.

To form a W layer to be polished, a high-temperature oxide (HTO) film was deposited over a silicon substrate to a thickness of 1000 Å, and a TiN layer and the W layer were deposited in succession to a thickness of 1000 A and 10000 A, respectively. To form a Ti layer as another target to be polished, an HTO layer and a Ti layer were deposited over a silicon substrate in succession to a thickness of 1000 A and 2000 A, respectively.

The polishing was carried out using the same tool as in Example 1 under the same conditions, except that a down force of 5 psi was applied. The results obtained from the CMP with the six sample slurries are shown in Table 3.

TABLE 1

| | | | | W | Ti | |
|---|---|---|---|---|---|---|
| | Amount of | Amount of | Amount of | Removal | Removal | |
| Sample | H₂O₂ | Fe(NO₃)₃ | conc. HF (% | Rate | Rate | Selectivity |
| No. | (% by weight) | (% by weight) | by volume) | (Å/min) | (Å/min) | (W:Ti) |
| 1 | 2 | 0.05 | 0 | 3628 | 588 | 6.2:1 |
| 2 | 2 | 0.05 | 0.01 | 3221 | 744 | 4.3:1 |
| 3 | 2 | 0.1 | 0 | 3780 | 604 | 6.1:1 |
| 4 | 2 | 0.1 | 0.01 | 3329 | 773 | 4.3:1 |
| 5 | 2 | 0.2 | 0 | 4778 | 698 | 6.8:1 |
| 6 | 2 | 0.2 | 0.01 | 4481 | 698 | 6.4:1 |

As shown in Table 3, as for the samples with HF, a slight reduction in the W removal rate is shown, but there is an increase in the Ti removal rate. As a result, the selectivity of the slurry to the W layer over the Ti layer decreases. Meanwhile, for the samples with increased amount of Fe(NO₃)₃, due to a relative increase in the W removal rate, a slight difference is shown in the selectivity between the samples with and without HF.

Example 4: Evaluation of slurry characteristics with respect to the amount of corrosion inhibitor

The removal rate of a W layer with respect to the amount of corrosion inhibitor added to the second solution was evaluated.

H₂O₂ and Fe(NO₃)₃ were used as the first and second oxidizing agents, respectively, and EDTA-diammonium salt hydrate was used as corrosion inhibitor. While the amounts of H₂O₂ and Fe(NO₃)₃ were fixed at 2% and 0.05% by weight, respectively, based on the total weight of the slurry, the amount of EDTA-diammonium salt hydrate was varied at 0, 0.005, 0.01, 0.05 and 0.1% by weight based on the total weight of the slurry, thereby resulting in 5 sample slurries.

To form a W layer to be polished, a high-temperature oxide (HTO) film was deposited over a silicon substrate to a thickness of 1000 Å, and a TiN layer and the W layer were deposited in succession to a thickness of 1000 Å and 10000 Å, respectively.

The silicon substrate with the Ti layer was dipped in each of the 5 sample slurries for wet etching. The results are shown in Table 4.

TABLE 4

| | | | Amount of EDTA- | |
|---|---|---|---|---|
| | | | diammonium salt | W Corrosion |
| | Amount of H₂O₂ | Amount of Fe(NO₃)₃ | hydrate (% by | rate |
| Sample No. | (% by weight) | (% by weight) | weight) | (Å/min) |
| 1 | 2 | 0.05 | 0 | 126 |
| 2 | 2 | 0.05 | 0.005 | 87 |
| 3 | 2 | 0.05 | 0.01 | 54 |
| 4 | 2 | 0.05 | 0.05 | 43 |
| 5 | 2 | 0.05 | 0.1 | 27 |

As shown in Table 4, with the increase amount of EDTA-diammonium hydrate, the W corrosion rate decreases.

According to the CMP slurry of the present invention, the oxidizing ability of an oxidizing agent that is reduced by oxidizing metal is restored by another oxidizing agent, whereby the metal removal rate of the slurry is enhanced using a smaller overall amount of oxidizing agent. Also, the CMP slurry preferably contains a stabilizer of organic acid, so that the stability of the slurry over time is improved. In addition, the CMP slurry may further includes a corrosion inhibitor of EDTA or an EDTA salt, which is able to suppress corrosion of metal, and a fluorine compound that helps reduce a difference in removal rates of the metal layer and a barrier layer by increasing the barrier removal rate. As such, corrosion of metal and erosion of an oxide layer can be minimized or avoided.

In the preparation of a CMP slurry according to the present invention, prior to preparing a desired final CMP slurry, a first solution containing a first oxidating agent having a relative strong oxidizing ability, and a second solution containing a second oxidizing agent having a good reactivity to metal are separately prepared. Then, just before the CMP process, the first and second solutions are mixed at a predetermined ratio. As a result, a slurry with improved reproducibility can be obtained, thus improving the reproducibility of CMP process itself.

In the metallization of a semiconductor device according to the present invention, a reduction in thickness of the metal layer, due to corrosion by slurry, can be avoided. In addition, when the metal layer, the barrier layer and the oxide layer formed over a substrate are simultaneously exposed to CMP, the oxide layer can be protected from erosion which is otherwise caused by the different removal rates of the layers.

While this invention has been particularly shown and described with reference to preferred embodiments thereof, it will be understood by those skilled in the art that various changes in form and details may be made thereto without departing from the spirit and scope of the invention as defined by the appended claims.

What is claimed is:

1. A slurry comprising:
an abrasive;
a plurality of oxidizing agents;
a stabilizer including an organic acid having a carboxyl group;
a corrosion inhibitor which suppresses corrosion of a metal;
a fluorine compound which reduces a difference between a removal rate of a metal layer and a removal rate of a barrier layer; and
deionized water,
wherein the plurality of oxidizing agents includes a second oxidizing agent which oxidizes the metal and a first oxidizing agent which restores an oxidizing ability of the second oxidizing agent.

2. The slurry of claim 1, wherein the abrasive includes at least one of silica, alumina, ceria, titania, zirconia and germania.

3. The slurry of clam 2, wherein an amount of the abrasive is 3-25% by weight based on a total weight of the slurry.

4. The slurry of claim 1, wherein the first oxidizing agent includes at least one of hydrogen peroxide, benzoyl peroxide, calcium peroxide, barium peroxide and sodium peroxide.

5. The slurry of claim 4, wherein an amount of the first oxidizing agent is 0.01-10% by weight based on the total weight of the slurry.

6. The slurry of claim 1, wherein the second oxidizing agent includes at least one of ferric nitrate, potassium ferricyanide, ferric phosphate and ferric sulfate.

7. The slurry of claim 6, wherein an amount of the second oxidizing agent is 0.001-5% by weight based on a total weight of the slurry.

8. The slurry of claim 1, wherein the stabilizer includes at least one of acetic acid, citric acid, glutaric acid, glycolic acid, formic acid, lactic acid, malic acid, maleic acid, oxalic acid, phthalic acid, succinic acid and tartaric acid.

9. The slurry of claim 8, wherein an amount of the stabilizer is 0.01-10% by weight based on the total weight of the slurry.

10. The slurry of claim 1, wherein the corrosion inhibitor includes at least one of ethylenediaminetetraacetic acid (EDTA) or an EDTA salt.

11. The slurry of claim 10, wherein an amount of the corrosion inhibitor is 0.001-0.1% by weight based on a total weight of the slurry.

12. The slurry of claim 1, wherein the fluorine compound includes at least one of hydrofluoric acid (HF), fluorosilicic acid (H₂SiF₆), fluorotitanic acid (H₂TiF₆), fluoroboric acid (HBF₄), ammonium fluoride (NH₄F), ammonium hydrogen difluoride (NH₄HF₂), potassium fluoride (KF), potassium hydrogen difluoride (KHF₂), sodium fluoride (NaF), silver fluoride (AgF) and potassium tetrafluoroborate (KBF₄).

13. The slurry of claim 12, wherein an amount of the fluorine compound is 0.01-1% by volume based on a total volume of the slurry.

14. The slurry of claim 1, further comprising a pH adjuster.

15. The slurry of claim 14, wherein the pH adjuster includes at least one of sulfuric acid, nitric acid, hydrochloric acid and phosphoric acid.

16. The slurry of claim 1, wherein the slurry has a pH of 2 to 3.

17. The slurry of claim 1, wherein the first oxidizing agent includes at least one of hydrogen peroxide, benzoyl peroxide, calcium peroxide, barium peroxide and sodium peroxide, and wherein the second oxidizing agent includes at least one of ferric nitrate, potassium ferricyanide, ferric phosphate and ferric sulfate.

18. The slurry of claim 17, wherein the abrasive includes at least one of silica, alumina, ceria, titania, zirconia and germania, wherein the stabilizer includes at least one of acetic acid, citric acid, glutaric acid, glycolic acid, formic acid, lactic acid, malic acid, maleic acid, oxalic acid, phthalic acid, succinic acid and tartaric acid, and wherein the fluorine compound includes at least one of hydrofluoric acid (HF), fluorosilicic acid (H₂SiF₆), fluorotitanic acid (H₂TiF₆), fluoroboric acid (HBF₄), ammonium fluoride (NH₄F), ammonium hydrogen difluoride (NH₄HF₂), potassium fluoride (KF), potassium hydrogen difluoride (KHF₂), sodium fluoride (NaF), silver fluoride (AgF) and potassium tetrafluoroborate (KBF₄).

19. The slurry of claim 18, wherein an amount of the abrasive is 3-25% by weight based on a total weight of the slurry, wherein an amount of the first oxidizing agent is 0.01-10% by weight based on the total weight of the slurry, wherein an amount of the second oxidizing agent is 0.001-5% by weight based on a total weight of the slurry, wherein an amount of the stabilizer is 0.01-10% by weight based on the total weight of the slurry, wherein an amount of the corrosion inhibitor is 0.001-0.1% by weight based on a total weight of the slurry, and wherein an amount of the fluorine compound is 0.01-1% by volume based on a total volume of the slurry.

20. The slurry of claim 19, wherein the slurry has a pH of 2 to 3.

21. A slurry comprising:
a first solution including a first oxidizing agent, an abrasive and deionized water; and
a second solution including a second oxidizing agent which oxidizes a metal, a stabilizer which includes an organic acid having a carboxyl group, a corrosion inhibitor which suppresses corrosion of the metal, a fluorine compound which reduces a difference in removal rates of a metal layer and a barrier layer, and deionized water;
wherein the first oxidizing agent of the first solution restores an oxidizing ability of the second oxidizing agent of the second solution.

22. A method for preparing a slurry, comprising:
preparing a first solution including a first oxidizing agent, an abrasive and deionized water;
preparing a second solution including a second oxidizing agent which oxidizes a metal, a stabilizer which includes an organic acid having a carboxyl group, a corrosion inhibitor which suppresses corrosion of the metal, a fluorine compound which reduces a difference in removal rates of a metal layer and a barrier layer, and deionized water;
diluting the first solution with deionized water; and
mixing the diluted first solution with the second solution;
wherein the first oxidizing agent of the first solution restores an oxidizing ability of the second oxidizing agent of the second solution.

23. The method of claim 22, wherein the first oxidizing agent includes at least one of hydrogen peroxide, benzoyl peroxide, calcium peroxide, barium peroxide and sodium peroxide.

24. The method of claim 22, wherein the abrasive includes at least one of silica, alumina, ceria, titania, zirconia and germania.

25. The method of claim 22, wherein the second oxidizing agent includes at least one of ferric nitrate, potassium ferricyanide, ferric phosphate and ferric sulfate.

26. The method of claim 22, wherein the stabilizer includes at least one of acetic acid, citric acid, glutaric acid, glycolic acid, formic acid, lactic acid, malic acid, maleic acid, oxalic acid, phthalic acid, succinic acid and tartaric acid.

27. The method of claim 22, wherein the corrosion inhibitor includes at least one of ethylenediaminetetraacetic acid (EDTA) and an EDTA salt.

28. The method of claim 22, wherein the fluorine compound includes at least one of hydrofluoric acid (HF), fluorosilicic acid (H₂SiF₆), fluorotitanic acid (H₂TiF₆), fluoroboric acid (HBF₄), ammonium fluoride (NH₄F), ammonium hydrogen difluoride (NH₄HF₂), potassium fluoride (KF), potassium hydrogen difluoride (KHF₂), sodium fluoride (NaF), silver fluoride (AgF) and potassium tetrafluoroborate (KBF₄).

29. The method of claim 22, further comprising adjusting a pH of the second solution.

30. A method of metallization of a semiconductor device, comprising:
forming a barrier layer over an oxide layer having a stepped surface;
forming a metal layer over the barrier layer;
providing a slurry comprising (a) an abrasive, (b) a plurality of oxidizing agents, (c) a stabilizer including an organic acid having a carboxyl group, (d) a corrosion inhibitor which suppresses corrosion of a metal, (e) a fluorine compound which reduces a difference between a removal rate of the metal layer and a removal rate of the barrier layer, and (f) deionized water, wherein the plurality of oxidizing agents includes a second oxidizing agent which oxidizes the metal and a first oxidizing agent which restores an oxidizing ability of the second oxidizing agent; and
removing a portion of the metal layer and the barrier layer by chemical mechanical polishing using slurry.

31. The method of claim 30, wherein the barrier layer is formed of Ti, TiN, Ta or TaN.

32. The method of claim 30, wherein the metal layer is formed of W, Al or Cu.
